(19) United States
(12) Patent Application Publication
(10) Pub. No.: US 2021/0255554 A1
(43) Pub. Date: Aug. 19, 2021

(54) MODULE FOR A PROJECTION EXPOSURE APPARATUS FOR SEMICONDUCTOR LITHOGRAPHY WITH A SEMI-ACTIVE SPACER, AND METHOD FOR USING THE SEMI-ACTIVE SPACER

(71) Applicant: Carl Zeiss SMT GmbH, Oberkochen (DE)

(72) Inventors: Thilo Pollak, Neresheim (DE); Dietmar Duerr, Dettingen (DE)

(21) Appl. No.: 17/307,363

(22) Filed: May 4, 2021

Related U.S. Application Data
(63) Continuation of application No. PCT/EP2019/079182, filed on Oct. 25, 2019.

(30) Foreign Application Priority Data
Nov. 29, 2018 (DE) 102018220565.5

(51) Int. Cl. G03F 7/20

(52) U.S. Cl. CPC G03F 7/70825; G03F 7/70258

(57) ABSTRACT

A module for a projection exposure apparatus for semiconductor lithography includes at least one optical element arranged in a holder. At least one spacer is arranged between the holder and a further holder or a main body. The spacer is designed to semi-actively vary its extent. A method for positioning at least one holder in a projection exposure apparatus for semiconductor lithography includes using a semi-active spacer is to position the holder.

### CROSS-REFERENCE TO RELATED APPLICATIONS

The present application is a continuation of, and claims benefit under 35 USC 120 to, international application PCT/EP2019/079182, filed Oct. 25, 2019, which claims benefit under 35 USC 119 of German Application No. 10 2018 220 565.5, filed Nov. 29, 2018. The entire disclosure of these applications are incorporated by reference herein.

### FIELD

The disclosure relates to a module for a projection exposure apparatus for semiconductor is lithography with a semi-active spacer, and to a method for using the semi-active spacer.

### BACKGROUND

Projection exposure apparatuses for semiconductor lithography include a multiplicity of zo optical elements which are held in holders, which in turn are connected to one another to form a projection optical unit, wherein the optical elements are arranged relative to one another in accordance with the respective design specifications. During the alignment of the holders, designed as mounts, in the case of refractive projection optical units which include rotationally symmetrical lenses and possibly mirrors, the mounts are aligned relative to one another in the three translational degrees of freedom x, y and z and about the rotational degree of freedom Rot z. Here, the z direction corresponds to the direction of the used light, that is to say of the light that is used for imaging structures of a lithography mask, for example of a phase mask, of a so-called reticle, onto a semiconductor substrate, a so-called wafer. The spacing between two optical elements in the z direction is set using so-called adjustment rings, which are designed as highly precise plane-parallel rings which attain thickness tolerances in the range of a few micrometres [μm]. The two other translational degrees of freedom x and y, which are aligned perpendicular to the z direction, are adjusted by displacement of the mounts and adjustment rings in the x-y plane. The rotational degree of freedom Rot z is addressed via rotation of the mount about the z axis, which also corresponds to the optical axis. Rotation about the x (Rot x) s and y axes (Rot y) optically corresponds, in the case of spherical surfaces, to a translation in the x and y directions, whereby these degrees of freedom are already covered by displacement in the x-y plane.

In the case of EUV projection exposure apparatuses, in the case of which it is generally no longer possible to use refractive optical elements owing to the very short wavelength of the used radiation of less than 30 nm, in particular 13.5 nm, the mirrors that are used are arranged in modules. To align the modules relative to one another in all six degrees of freedom, high-accuracy spacers, hereinafter referred to as spacers, are used between the connection points of the modules to the base frame of the projection exposure apparatus. The spacers are adapted in an iterative process until such time as the modules have been aligned relative to one another within the given tolerances.

In the event that a module or a mount needs to be exchanged in the field with the customer, the new module is installed again such that the alignment of the optical elements relative to one another corresponds to the alignment prior to the exchange. Here, the different geometries of the modules and the different position and orientation of the optical elements in the modules are determined and, based on this, a new set of spacers, that is to say a number of several spacers, are produced. Owing to non-deterministic influences of the screw connection and tolerances in the determination of the geometry of the modules and of the position and orientation of the optical elements therein, the alignment with the method described further above is often possible only with highly time-consuming iterative steps.

With these methods, it is often only possible to achieve position accuracies of 10-15 μm, wherein the desired properties in current systems can lie in a range of less than 1 μm, specifically if a module or a mount has to be exchanged in the field.

One method involves actuators as spacers, such as for example piezoelectric actuators. However, in order to maintain the extent of the actuator, a voltage, the so-called offset voltage, is applied and, furthermore, owing to voltage fluctuations and material-inherent hysteresis effects, relatively cumbersome closed-loop control is often used in order to be able to hold the set extent over a relatively long period of time. In a further variant, the actuators that are used for positioning the optical elements during operation may also be used for correcting the position and orientation of the module. This has the result that the demands on the travel of the actuators can increase, and thus the ratio of the magnitude of the travel and the accuracy of the adjustment can become very large, which can have an adverse effect on the production costs and complexity and thus the susceptibility to faults of the actuators.

### SUMMARY

The present disclosure seeks to provide an improved device. The disclosure also seeks to provide a method for using semi-active spacers in a projection exposure apparatus. In an aspect, the disclosure provides a module for a projection exposure apparatus for semiconductor lithography, which includes at least one optical element arranged in a holder, wherein at least one spacer is arranged between the holder and a further holder or a main body, which spacer is designed to semi-actively vary its extent. Several of the holders with optical elements may be part of a projection lens, wherein, for example, the spacing between the optical elements can be adjusted via semi-active spacers. In this context, semi-active means firstly that the spacer is activated only at particular points in time, for example during the initial setup of a projection exposure apparatus. Secondly, semi-active also means that the spacer has to be connected to an open-loop or closed-loop control unit only when its shape is to be changed and it maintains the changed shape in stable fashion in the range of a few nanometres, in particular less than 100 nm, in particular less than 20 nm, in particular less than 5 nm over a long period of time even without a further supply of energy, that is to say involves only a temporary supply of energy for the purposes of adjustment.

The spacer may for example be in the form of a washer, that is to say can include a round shape with an aperture in the centre. For the assembly of the spacer, the latter can be arranged between two components, the spacing of which to one another can be adjusted. The two components may be connected to one another with a screw, for example, with an expansion screw, wherein the screw is in this case led through the aperture of the spacer. The spacer may include a piezoelectric material. Piezoelectric materials normally involve a so-called offset voltage in order to effect a change in shape. The magnitude of the offset voltage is proportional to the deflection. If the offset voltage is reduced or the piezo is disconnected from the voltage source, the piezoelectric material returns into its original state again, wherein the deflection is afflicted with hysteresis. New developments, such as the PIRest series from the company Physik Instrumente GmbH, maintain the shape after disconnection of the voltage source, and in so doing are highly stable with regard to drift.

In one variant of the disclosure, an intermediate element may be arranged between the holder and the spacer or between the holder and the main body. The intermediate element may for example serve for compensating a large spacing in the range of millimetres, wherein the semi-active spacer can compensate only relatively small spacings for example in the range of μm.

The intermediate element may furthermore be designed as a passive spacer. The intermediate element may for example be a so-called adjustment ring, such as is used in modern systems for adjusting the spacing between two holders.

In some embodiments of the disclosure, a first holder may be mounted on a second holder or on a main body in a statically determinate manner. The static mounting, which commonly takes the form of a three-point mounting, can have the effect that the upper holder lies in a defined manner on three points, which can advantageously reduce the deformation of the holder during the screw connection owing to further contact points.

Additionally, a first holder may be mounted on a second holder or on a main body in a statically overdeterminate manner. A feature of the overdeterminate mounting can include that the connection between a first holder and a second holder or a main body can be designed to be more rigid than in the case of a statically determinate mounting. Depending on the design of the holder, deformations arising as a result of the overdeterminate mounting can be reduced, e.g., to a minimum.

In one variant of the disclosure, an open-loop and closed-loop control device may be configured for controlling the at least one spacer in order to adjust the spacing between two holders or between a holder and a main element. The open-loop and closed-loop control device may be configured such that it can control multiple semi-active spacers in parallel and/or series. This can have the advantage that the number of open-loop and closed-loop control devices can be reduced, which can have a positive effect on the production costs.

Furthermore, multiple spacers may be arranged such that the holder is deformed as a result of movement of the spacers. Here, the holder may be designed such that a deformation of the holder can be transmitted to the optical element held by the holder. In this case, the spacers can not only be used for adjusting the spacing but form, together with the holder, a position or deformation manipulator, which can advantageously improve the imaging quality of the projection exposure apparatus through targeted deformation of the optical element.

For example, a seal may be arranged between the two holders or between the holder and the main body. The seal seals, for example, the interior of the projection optical unit with respect to the surroundings, such that controlled ambient conditions for the optical elements can be maintained in the projection optical unit. The travels of the semi-active spacers designed as a three-point or multi-point support may in this case be much shorter than the compression of the seal caused by the preload of the seal, which is designed for example as an O-ring, such that the sealing action can be ensured at all times despite movement of the spacers.

The disclosure provides methods for positioning at least one holder in a projection exposure apparatus for semiconductor lithography, which include using a semi-active spacer for positioning the holder. This can have the feature that the spacings between the holders or the holder and a main body can be adjusted in the range of a few nm without releasing s the holder, assembling an adapted spacer and producing a screw connection again.

For example, a method of the type may include the following method steps:
a) assembling the at least one semi-active spacer onto a first holder, a second holder or a main body,
b) assembling the holder onto the at least one spacer or the second holder or the main body, wherein the spacer is arranged between the first holder and the second holder and the main body,
c) connecting the spacer to an open-loop and closed-loop control device,
d) determining the position and orientation of the first holder relative to the second and holder or the main body,
e) determining the deviation of the position and orientation from the setpoint position and setpoint orientation,
f) aligning the holder on the basis of the determined deviation via a temporary supply of energy via the open-loop and closed-loop control device,
g) checking the position and orientation of the holder,
h) repeating steps d) to g) until the setpoint position and setpoint orientation has been attained.

Different degrees of freedom can be adjusted depending on the arrangement and number of the spacers. For example, with three spacers arranged offset by 120° , it is possible to adjust, with suitable control of the spacers, the spacing in an extent direction of the spacers and a degree of tilt about two axes which are arranged perpendicular to the extent direction and to one another. In the case of six spacers, it is for example possible for six degrees of freedom to be adjusted, as is commonly involved in the alignment of mirrors. In order to decouple the spacers in order to reduce crosstalk between the various degrees of freedom to a minimum, the spacers may be connected to decoupling elements.

In one variant of the disclosure, the method may include the following steps:
a) assembling the holders, wherein an intermediate element is arranged at least between a first and a second holder for the purposes of presetting the spacing between the holders and/or wherein the at least one semi-active spacer is arranged at least between a first and a second holder for the purposes of adjusting the spacing between the holders,
b) connecting the spacer to an open-loop and closed-loop control device,
c) determining the imaging aberrations of the projection exposure apparatus,
e) determining the travel of the at least one semi-active spacer for the purposes of correcting the imaging aberrations,
f) moving the spacer via a temporary supply of energy via an open-loop and closed-loop control device,
g) checking the imaging,
h) repeating steps c) to g) until the imaging lies within a set tolerance.

In some embodiments, the method may include the following method steps:
a) uninstalling the first holder,
b) installing the new holder with the semi-active spacer,
c) connecting the spacer to an open-loop and closed-loop control device,
d) determining the position and orientation of the holder relative to the second holder or the main body,
e) determining the deviation of the position and orientation from the setpoint position and setpoint orientation,
f) aligning the holder in accordance with the determined deviation via a temporary supply of energy via the open-loop and closed-loop control device,
g) checking the position and orientation of the holder,
h) repeating steps d) to g) until the setpoint position and setpoint orientation has been attained.

Furthermore, the method, wherein the semi-active spacer is at least temporarily connected to an open-loop and closed-loop control device, may include the following steps:
a) determining the imaging aberrations of the projection exposure apparatus,
b) determining the travel of the semi-active spacer,
c) moving the semi-active spacer by the predetermined travels via a temporary supply of energy,
d) checking the imaging aberrations,
e) repeating steps b) to d) until the imaging aberrations lie within a set tolerance.

Here, after the determination of the imaging aberrations, the travels may be determined such that all imaging aberrations of the projection exposure apparatus are minimized. Alternatively, the travels may also be determined such that the imaging is intentionally detuned, that is to say includes certain imaging aberrations which are advantageous for the manufacturing process, which is also influenced by process parameters other than the imaging quality.

Furthermore, in addition to the semi-active spacers, additional intermediate elements may be used as passive spacers.

For example, after the final method step, the semi-active spacers may be disconnected from the open-loop and closed-loop control device. In this way, multiple semi-active spacers can be activated using only one open-loop and closed-loop control device, which can have an advantageous effect on the production costs of the projection exposure apparatus. After the adjustment of the spacers in the context of an alignment of the machine, the cables can be detached from the spacers, which firstly can reduce the introduction of vibrations from the surroundings to the machine, and secondly can save structural space, which can be used for other purposes during the operation of the machine.

Here, the position and orientation of the holder may for example be determined by an external measurement mechanism. This may be for example simple switches or spacing sensors, which can, depending on the type of construction, be at least temporarily attached to one or both holders or to the holder and/or to the main body.

Furthermore, the position and orientation of the holder may be determined indirectly via a wavefront measurement of the projection exposure apparatus. During the initial assembly of the projection exposure apparatus, a wavefront measurement may be performed after the initial assembly and alignment of the holders. This may be evaluated on the basis of models, and the travels for the individual spacers determined from the results. The values thus determined may then for example be transmitted to a central open-loop and closed-loop control device, which moves the semi-active spacers into the setpoint position. In this way, the varying deformations that arise as a result of the loosening and retightening of the screw connections between the holders or the holder and the main body can be avoided. The measurement of the wavefront may also be used for using the spacers as deformation manipulators. On the basis of the wavefront measurement, the deformation for the correction of the wavefront can be determined on the basis of models and likewise transmitted to an open-loop and closed-loop control device for the control of the semi-active spacers.

### BRIEF DESCRIPTION OF THE DRAWINGS

Illustrative embodiments and variants of the disclosure are explained in more detail below with reference to the drawing, in which:

FIG. 1 shows the basic construction of an EUV projection exposure apparatus,

FIG. 2 shows the basic construction of a DUV projection exposure apparatus,

FIG. 3 shows a detail view of a first embodiment of the disclosure,

FIG. 4 shows a further detail view of the disclosure,

FIG. 5 shows a further embodiment of the disclosure, and

FIG. 6 shows a further embodiment of the disclosure.

### DESCRIPTION OF ILLUSTRATIVE EMBODIMENTS

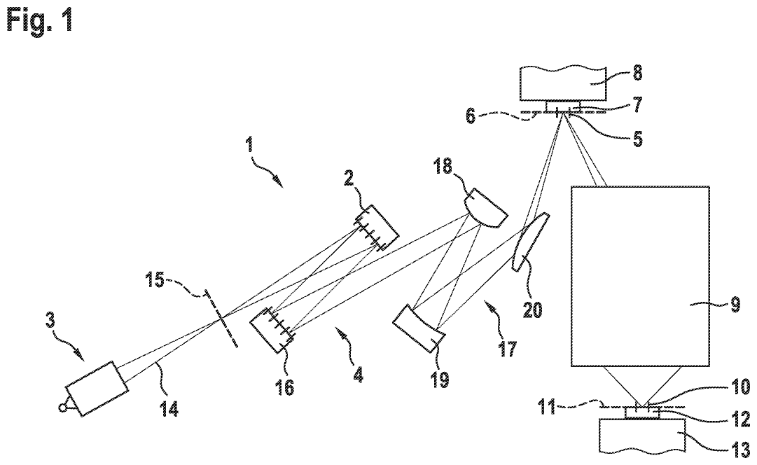

FIG. 1 shows an example of the basic construction of a microlithographic EUV projection exposure apparatus 1, in which the disclosure can find use. An illumination system of the projection exposure apparatus 1 has, in addition to a light source 3, an illumination optical unit 4 for the illumination of an object field 5 in an object plane 6. EUV radiation 14 in the form of optical used radiation generated by the light source 3 is aligned via a collector, which is integrated in the light source 3, in such a way that the radiation passes through an intermediate focus in the region of an intermediate focal plane 15 before it is incident on a field facet mirror 2. Downstream of the field facet mirror 2, the EUV radiation 14 is reflected by a pupil facet mirror 16. With the aid of the pupil facet mirror 16 and an optical assembly 17 having mirrors 18, 19 and 20, field facets of the field facet mirror 2 are imaged into the object field 5.

A reticle 7, which is arranged in the object field 5 and held by a schematically illustrated reticle holder 8, is illuminated. A projection optical unit 9, illustrated merely schematically, serves for imaging the object field 5 into an image field 10 in an image plane 11. A structure on the reticle 7 is imaged onto a light-sensitive layer of a wafer 12, which is arranged in the region of the image field 10 in the image plane 11 and is held by a wafer holder 13 that is likewise illustrated in part. The light source 3 can emit used radiation in particular in a wavelength range of between 5 nm and 30 nm.

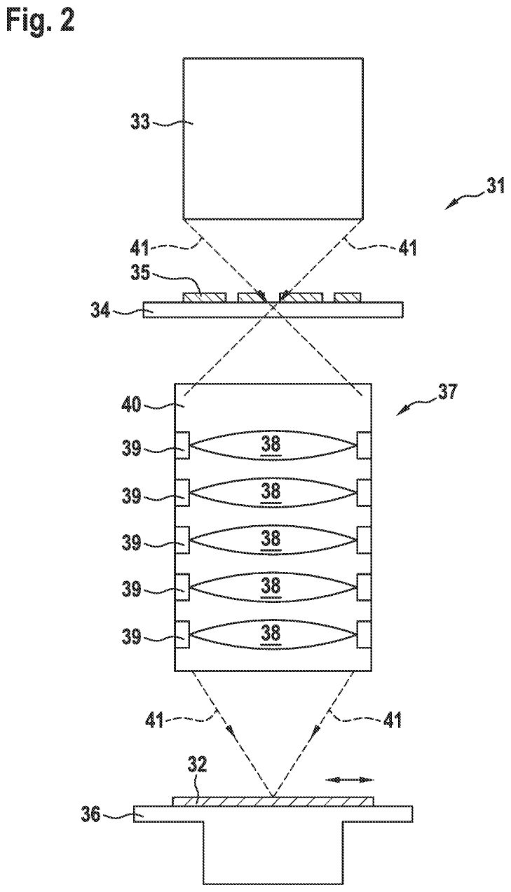

The disclosure may likewise be used in a DUV projection exposure apparatus 31, which is illustrated in FIG. 2. This uses used radiation in a wavelength range from 100 nm to 300 nm.

The projection exposure apparatus 31 serves for the exposure of structures on a substrate which is coated with photosensitive materials, and which, in some embodiments, generally consists predominantly of silicon and is referred to as a wafer 32, for the production of semiconductor components, such as computer chips.

The projection exposure apparatus 31 in this case substantially includes an illumination device 33, a reticle stage 34 for receiving and exactly positioning a mask provided with a structure, a so-called reticle 35, by which the later structures on the wafer 32 are determined, a wafer stage 36 for holding, moving and exactly positioning specifically the wafer 32 and an imaging device, to be specific a projection lens 37, with multiple optical elements 38, which are held by way of mounts 39 in a lens housing 40 of the projection lens 37.

The basic functional principle in this case provides that an image of the structures introduced into the reticle 35 is projected onto the wafer 32, the imaging generally being on a reduced scale.

The illumination device 33 provides a projection beam 41 in the form of electromagnetic radiation, which is used for the imaging of the reticle 35 on the wafer 32. A laser, plasma source or the like may be used as the source of this radiation. Optical elements in the illumination device 33 are used to shape the radiation in such a way that, when it is incident on the reticle 35, the projection beam 41 has the desired properties with regard to diameter, polarization, form of the wavefront and the like.

An image of the reticle 35 is produced by the projection beam 41 and transferred from the projection lens 37 onto the wafer 32 in an appropriately reduced form, as already explained above. In this case, the reticle 35 and the wafer 32 may be moved synchronously, so that images of regions of the reticle 35 are projected onto corresponding regions of the wafer 32 virtually continuously during a so-called scanning operation. The projection lens 37 has a multiplicity of individual refractive, diffractive and/or reflective optical elements 38, such as for example lens elements, mirrors, prisms, terminating plates and the like, wherein the optical elements 38 can be actuated for example via one or more of the actuator arrangements described here.

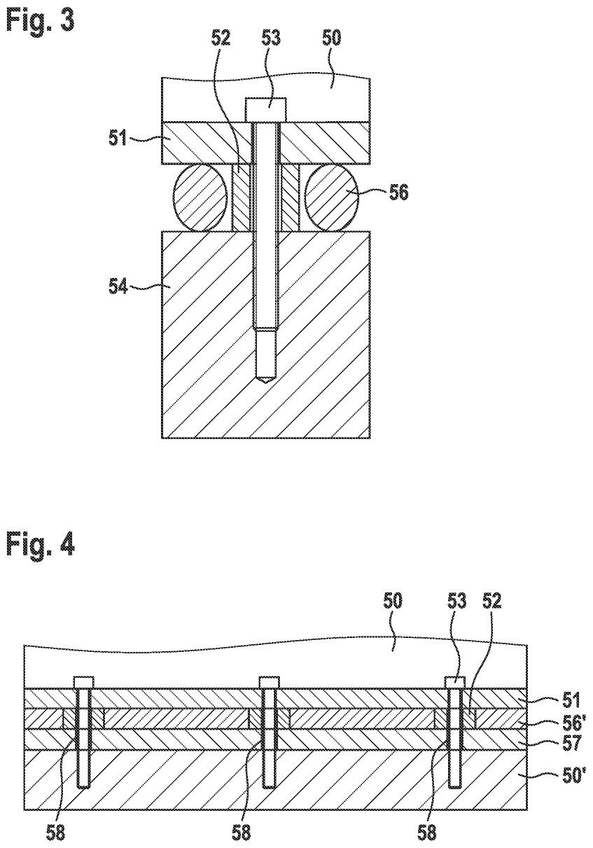

FIG. 3 is a schematic illustration of a main body 54, for example the lens housing illustrated in FIG. 2, and of a holder 50, for example the mount illustrated in FIG. 2, wherein the holder 50 includes a flange 51. A semi-active spacer 52 is arranged between the flange and the main body 54. The semi-active spacer is designed as a ring, such that a screw 53, which may for example be designed as an expansion screw, firstly connects the flange 51 and the main body 54, and secondly, the spacer 52 is preloaded. To seal the connection, a seal designed as an O-ring 56 is likewise arranged between the flange 51 and the main body 54. The travels of the semi-active spacers 52 are in this case much shorter than the compression of the seal 56, such that the sealing action is ensured at all times. A further seal may optionally be arranged on the other side of the spacers 52.

FIG. 4 is a schematic illustration of two holders 50, 50′, wherein a first holder 50 includes a flange 51. Arranged on the second holder 50′ is an intermediate element 57, which is designed for example as a passive spacer and which includes through-holes 58 for screws 53. Arranged between the intermediate element 57 and the flange 51 of the first holder 50 are semi-active spacers 52, which are designed as rings and through the opening of which the screws 53 extend for the purposes of connecting the first 50 and second holder 50′. Likewise arranged between the flange 51 and the intermediate element 57 is a seal designed for example as an O-ring 56′. The intermediate element 57 may, for example after initial assembly of the holders 50, 50′ and a determination of the setpoint spacing of the optical elements, be uninstalled again and reworked. After reassembly, the remaining deviation can be adjusted via the semi-active spacers 52. This has the advantage that the unpredictable deformations as a result of the screw connection of the two holders 50, 50′ can be reduced to a minimum.

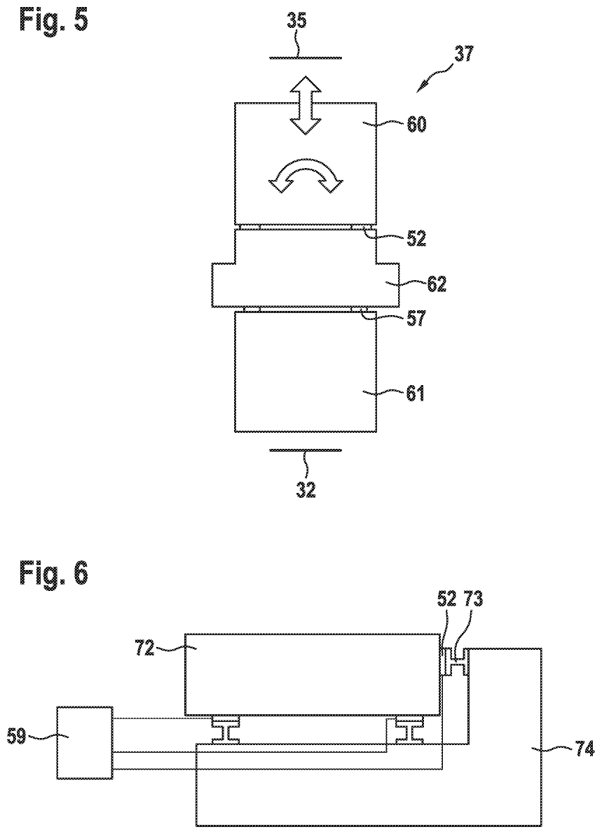

FIG. 5 is a further schematic illustration of a projection exposure apparatus, wherein, for the sake of clarity, the illumination device is not illustrated. The projection optical unit 37 includes an upper lens part 60 including multiple holders 52, a holder 62 designed as a module, and a lower lens part 61 including multiple holders 52. In the event that the module 62 has to be exchanged, the upper lens part 60 is removed and the module 62 is exchanged, wherein the module 62 is aligned relative to the lower lens part 61 via intermediate elements 57 designed as passive spacers. The semi-active spacers 52 described in FIGS. 3 and 4 are arranged on the module 62, onto which, in turn, the upper lens part 60 is assembled. The upper lens part 60 is aligned relative to the module 62 by movement of the semi-active spacers 52, wherein, for example, a statically determinate three-point mounting of the upper lens part 60 on the module 62 permits an adjustment of the tilt about two axes and an adjustment along the longitudinal axis of the projection optical unit.

FIG. 6 is a schematic illustration of a holder which is designed as a module 72 and which may be used in particular in EUV projection exposure apparatuses. The module 72 is designed for example as a mirror, wherein the module 72 is mounted in a main body 74 so as to be manipulable in six degrees of freedom. For the positioning of the module 72 on the main body 74, six semi-active spacers 52 are arranged on the module 72, wherein only three spacers are visible in FIG. 6 because the others are concealed. The spacers 52 are connected, for the movement thereof, to an open-loop and closed-loop control device 59. For the decoupling of the parasitic movements of the spacers 52 resulting from the movement of the respective other spacers 52, decoupling elements 73 are arranged between the spacers 52 and the main body 75, which decoupling elements are attached to the main body 74 rigidly only in the direction of action of the spacers 52 and are attached flexibly in the five other degrees of freedom.

In this context, flexible is intended to mean that the rigidity of the decoupling elements is configured to be as low as possible in the context of the design and the technical characteristics of the material used, such as for example yield strengths or flexural strengths. By contrast, rigid is to be understood to mean a greatest possible rigidity in the context of the design and the technical characteristics of the material used.

The semi-active spacers 52 may, in particular during an initial alignment of the modules 72 in the projection exposure apparatus, be used to position the modules 72 with such accuracy that the further actuators of the projection exposure apparatus, which for the sake of better clarity are not illustrated in FIG. 6, need to use virtually no travel for the alignment of the modules 72 for the purposes of positioning the modules 72 during operation. A feature can be that the actuators, in the case of which the ratio of the travels used during operation to the travels used during the alignment is commonly 1:100, in particular 1:50, in particular 1:10, can, through the use of the semi-active spacers, be configured with shorter travels and thus so as to be less expensive.

### LIST OF REFERENCE SIGNS

1 Projection exposure apparatus

2 Field facet mirror

3 Light source

4 Illumination optical unit

5 Object field

6 Object plane

7 Reticle

8 Reticle holder

9 Projection optical unit

10 Image field

11 Image plane

12 Wafer

13 Wafer holder

14 EUV radiation

15 Intermediate field focal plane

16 Pupil facet mirror

17 Assembly

18 Mirror

19 Mirror

20 Mirror

31 Projection exposure apparatus

32 Wafer

33 Illumination device

34 Reticle stage

35 Reticle

36 Wafer stage

37 Projection optical unit

38 Optical elements

39 Mounts

40 Lens housing

41 Projection beam

50, 50′ Holder

51 Flange

52 Semi-active spacer

53 Preloading mechanism (screw)

54 Main body

56, 56′ O-ring

57 Intermediate element

58 Through hole

59 Open-loop and closed-loop control device

60 Upper lens part

61 Lower lens part

62 Module

72 Module

73 Decoupling element

74 Main body

1. A module, comprising:
a holder;
an optical element in the holder; and
a spacer between the holder and a member selected from the group consisting of a further holder and a main body,
wherein the spacer is configured so that:
when the spacer is activated by a supply of energy, an extent of the spacer changes from a first extent to a second extent different from the first extent; and
after achieving the second extent, when the spacer is de-activated by removing the supply of energy, the spacer maintains the second extent to within 100 nanometers.

2. The module of claim 1, wherein, after achieving the second extent, when the spacer is de-activated by removing the supply of energy, the spacer maintains the second extent to within 20 nanometers.

3. The module of claim 1, wherein, after achieving the second extent, when the spacer is de-activated by removing the supply of energy, the spacer maintains the second extent to within five nanometers.

4. The module of claim 1, wherein the spacer comprises a piezoelectric material.

5. The module of claim 1, further comprising an intermediate element, wherein one of the following holds:
the intermediate element is between the holder and the spacer;
the member comprises the further holder, and the intermediate element is between the further holder and the spacer; and
the member comprises the main body, and the intermediate element is between the main body and the holder.

6. The module of claim 5, wherein the intermediate element comprises an adjustment ring.

7. The module of claim 1, wherein the holder is mounted on the member in a statically determinate manner.

8. The module of claim 7, wherein:
the module comprises a plurality of spacers; and
for each of the six degrees of freedom, a spacer of the plurality of spacers is between the holder and the member.

9. The module of claim 1, wherein the holder is mounted on the member in a statically overdeterminate manner.

10. The module of claim 1, further comprising an open-loop and closed-loop control device configured to control the spacer to adjust a spacing between the holder and the member.

11. The module of claim 1, wherein the module comprises a plurality of spacers configured so that movement of the spacers deforms the holder, and the deformation of the holder is transmitted to the optical element.

12. The module of claim 1, further comprising a seal between the holder and the member.

13. The module of claim 12, wherein the seal is a gas tight seal.

14. The module of claim 12, wherein the seal surrounds the spacer.

15. The module of claim 12, wherein the seal comprises an O-ring.

16. The module of claim 12, wherein the spacer comprises a washer.

17. The module of claim 12, wherein:
the member comprises the main body;
the module further comprises a decoupling element between the spacer and the main body; and
the decoupling element is stiff in a direction of action of the spacer.

18. The module of claim 1, wherein the member comprises the main body, and the module further comprises a decoupling element between the spacer and the main body.

19. The module of claim 1, wherein the optical element comprises a diffractive optical element or a reflective optical element.

20. An apparatus, comprising:
a module, comprising:
a holder;
an optical element in the holder; and
a spacer between the holder and a member selected from the group consisting of a further holder and a main body,
wherein the spacer is configured so that:
when the spacer is activated by a supply of energy, an extent of the spacer changes from a first extent to a second extent different from the first extent; and
after achieving the second extent, when the spacer is de-activated by removing the supply of energy, the spacer maintains the second extent to within 100 nanometers; and
wherein the apparatus is a semiconductor lithography projection exposure apparatus.

21. (canceled)

22. A method, comprising:
using a spacer to positioning a holder in a semiconductor lithography projection exposure apparatus,
wherein the spacer is configured so that:
when the spacer is activated by a supply of energy, an extent of the spacer changes from a first extent to a second extent different from the first extent; and
after achieving the second extent, when the spacer is de-activated by removing the supply of energy, the spacer maintains the second extent to within 100 nanometers.

23.-26. (canceled)
